(19) United States
(12) Patent Application Publication
(10) Pub. No.: US 2025/0098149 A1
(43) Pub. Date: Mar. 20, 2025

(54) ULTRA-THIN BODY ARRAY TRANSISTOR FOR 4F2

(71) Applicant: Applied Materials, Inc., Santa Clara, CA (US)

(72) Inventors: Tong LIU, Folsom, CA (US); Sony VARGHESE, Manchester, MA (US)

(73) Assignee: Applied Materials, Inc., Santa Clara, CA (US)

(21) Appl. No.: 18/884,775

(22) Filed: Sep. 13, 2024

Related U.S. Application Data
(60) Provisional application No. 63/584,065, filed on Sep. 20, 2023.

(51) Int. Cl. H10B 12/00; H01L 29/08

(52) U.S. Cl. CPC H10B 12/395; H10B 12/0383; H10D 62/151

(57) ABSTRACT

The present technology includes vertical cell array transistor (VCAT) that include a bit line arranged in a first horizontal direction and a word line arranged in a second horizontal direction. The arrays include a channel extending in a vertical direction generally orthogonal to the first direction and the second horizontal direction, such that the bit line intersects with a source/drain region of the plurality of channels, and the word lines intersect with gate regions of the plurality of channels. Arrays include where the channels have at least one source/drain region and a channel body disposed between the first end and the second end. Arrays include where the channel body has a thickness that is greater than or about 5% less than a thickness of at least a portion of the at least one source/drain region.

### CROSS-REFERENCES TO RELATED APPLICATIONS

This application claims the benefit of priority to U.S. Patent Application No. 63/584,065 filed Sep. 20, 2023, the contents of which are hereby incorporated by reference in their entirety for all purposes.

### TECHNICAL FIELD

This disclosure generally describes designs for a 4F² two-dimensional dynamic random access memory array. More specifically, this disclosure describes a 4F² memory array with an improved floating body effect.

### BACKGROUND

With advances in computing technology, computing devices are smaller and have increased processing power. Accordingly, increased storage and memory is needed to meet the devices' programming and computing needs. The shrinking size of the devices with increased storage capacity is achieved by increasing the number of storage units having smaller geometries.

Dynamic random-access memory (DRAM) architectures continue to scale down over time. For example, a one transistor, one capacitor (1T-1C) DRAM cell architecture has successfully scaled down from an 8F² size to a 6F² size (where F is the minimum feature size). Further design scheme changes from 6F² to 4F² may help further improve area density. In the 4F² DRAM scheme, a storage node (capacitor) and bit line are located at the top and bottom of a vertical cell transistor, leaving the channel completely isolated from the body. Due to this arrangement, the floating body effect, which is not an issue for current 8F² or 6F² DRAM cell architecture due to the body connection of the channels, becomes a major technical challenge for 4F² DRAM. Therefore, improvements in the art are needed.

### BRIEF SUMMARY

The present technology is generally directed to vertical cell array transistors (VCAT) and methods of making such transistors. VCATs may include one or more bit lines arranged in a first horizontal direction, one or more word lines arranged in a second horizontal direction, and one or more channels extend in a vertical direction that is generally orthogonal to the first horizontal direction and the second horizontal direction, such that the one or more word lines intersect with a gate region of the one or more channels. VCATs include where the one or more channels have at least one source/drain region at a first end, a second end, or both a first end and a second end of the one or more channels, and a channel body disposed between the first end and the second end. The channel body has a thickness that is greater than or about 5% less than a thickness of at least a portion of the at least one source/drain region.

In embodiments, VCATs include where the one or more channels includes a first source/drain region at a first end and a second source/drain region at the second end, where the channel body has a thickness that is greater than or about 5% less than a thickness of at least a portion of the first source/drain region and the second source/drain region. Additionally or alternatively, in embodiments, at least a portion of the source/drain region has a greater thickness than a second portion of the source/drain region. In further embodiments, greater than or about 20% of the at least one source/drain region has a thickness greater than the thickness of the channel body. Moreover, in embodiments, the at least one source/drain region has a contact end and an internal end, where the contact end has the thickness greater than the thickness of the channel body. In embodiments, the internal end of the at least one source/drain region has a thickness generally equal to the thickness of the channel body. In more embodiments, the channel body has a thickness that is greater than or about 10% less than a thickness of at least a portion of the first source/drain region and the second source/drain region. Furthermore, in embodiments, the channel body has a thickness of less than 11 nm. In embodiments, the channel body has a thickness of less than or about 10 nm.

The present technology is also generally directed to a vertical cell array transistor that includes a plurality of bit lines arranged in a first horizontal direction, a plurality of work lines arranged in a second horizontal direction, and a plurality of channels extending in a vertical direction that is generally orthogonal to the first horizontal direction and the second horizontal direction such that the plurality of word lines intersect with a gate region of the plurality of channels. The plurality of channels each have a first source/drain region at a first end, a second source/drain region at a second end, and a channel body disposed between the first end and the second end. The channel body has a thickness that is greater than or about 5% less than a thickness of at least a portion of the first source/drain region and the second source/drain region.

The present technology is also generally directed to methods of forming a vertical cell array transistor. Methods include etching a substrate to form one or more shallow trench isolations and a plurality of vertically extending channels. Methods include depositing a first protective dielectric material in the shallow trench isolation adjacent to a first source/drain region at a first end of the vertically extending channel. Methods include depositing a sacrificial dielectric material over the first protective dielectric material. Methods also include depositing a second protective dielectric material over the sacrificial dielectric material adjacent to a second source/drain region at a second end of the vertically extending channel. Methods include removing the sacrificial material, and reducing a thickness of the channel body of the one or more vertically extending channels, where the channel body is disposed between the first source/drain region and the second source/drain region.

In embodiments, methods include etching the second protective dielectric material to form a support mesh. Additionally or alternatively, methods include reducing a thickness of a portion of the first source/drain region, the second source/drain region, or a combination thereof. In further embodiments, methods include where the first protective dielectric material is deposited extending from the first end to a height that is generally coplanar with a top surface of the first source/drain region or less. In more embodiments, the sacrificial dielectric material is deposited extending from a top surface of the first protective dielectric material to a height that is greater than or generally coplanar with a bottom surface of the second source/drain region. In embodiments, the second protective dielectric material is deposited extending from a height that is greater than or generally coplanar with the bottom surface of the second source/drain region to the second end of the vertically extending channel. In more embodiments, methods include removing the first protective dielectric material and the second protective dielectric material, and depositing a gate dielectric layer and a gate metal around the perimeter of the one or more shallow trench isolations. Moreover, in embodiments, the channel body is reduced in thickness by greater than or about 5%. In further embodiments, reducing the thickness of the channel body includes a selective silicon etch, an oxidation and wet etch, or a combination thereof. In embodiments, methods include where the sacrificial dielectric material includes a material that can be selectively etched without etching the first protective dielectric material and the second protective dielectric material.

Such technology may provide numerous benefits over conventional systems and techniques. For example, the processes and systems may distribute holes across multiple channels, reducing hole accumulation effects. Additionally, the processes and systems may significantly reduce hole accumulation in the body of a 4F² DRAM device. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIG. 3A shows a perspective view of a semiconductor structure according to embodiments of the present technology with a dielectric material fill after shallow trench isolation formation.

FIG. 3B shows a perspective view of a semiconductor structure according to embodiments of the present technology patterned for second shallow trench isolation formation.

FIG. 3C shows a perspective view of a semiconductor structure according to embodiments of the present technology with a protective dielectric around first source/drain regions.

FIG. 3D shows a perspective view of a semiconductor structure according to embodiments of the present technology with a sacrificial spacer in shallow trench isolations.

FIG. 3E shows a perspective view of a semiconductor structure according to embodiments of the present technology with a second protective dielectric around second source/drain regions with a support mesh pattern.

FIG. 3F shows a perspective view of a semiconductor structure according to embodiments of the present technology with the second protective dielectric etched to expose the sacrificial spacer.

FIG. 3G shows a perspective view of a semiconductor structure according to embodiments of the present technology with the sacrificial spacer removed.

FIG. 3H shows a perspective view of a semiconductor structure according to embodiments of the present technology with thinned channels.

FIG. 3I shows a perspective view of a semiconductor structure according to embodiments of the present technology with the first and second protective dielectric materials removed.

FIG. 3J shows a perspective view of a semiconductor structure according to embodiments of the present technology with the word line etched, shallow trench isolations filled, and source/drain regions formed.

FIG. 3K shows a perspective view of a semiconductor structure according to embodiments of the present technology with bit line contacts formed.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities had been increasing by approximately 25% node over node. However, the node over node increase in bit density has trended down to closer to 20% for the more recent generations, mainly due to the challenges with scaling the cell area. Cell design architecture for modern DRAM technology has been based on 6F² geometry, where “F” is the minimum feature size for a given technology node. Switching from 6F² to 4F² cell architecture could result in a 33% increase in bit density at the same technology node. In addition, patterning difficulties for 4F² DRAM are greatly reduced as compared to 6F². This is due at least in part to the fact that in the 4F² DRAM scheme, the capacitor and bit line are located at two ends of a vertical cell transistor, instead of tightly packed on the same side as in 6F² DRAM.

However, the 4F² DRAM design comes with its own challenges. For example, 4F² memory cells have the transistor channel disposed between the bitline and the capacitor layers, leaving no common substrate connecting the channels, resulting in a floating body effect for these transistors. For instance, it is believed that conventional 4F² DRAM devices exhibit off-leakage current issues. Off-leakage current results from the floating body effect, such as hole accumulation in the body of a 4F² DRAM device due to the isolated channels. Electron-hole pairs can form in a semiconductor channels due to band-to-band tunneling. While the electrons can flow into the n-type source or drain regions of the transistor, the holes cannot. For 4F² DRAM devices without a substrate connection, the holes have no path to leave the channel and will continue to accumulate. Thus, the floating body effect may lead to channel activation without gate activation, which eventually translates into leakage current from the capacitor, or data storage side of the device. Attempts have been made to provide body connections utilizing a buried body contact scheme. However, such attempts can result in gate overlap to a source/drain junction edge, allowing undesired gate-induced drain leakage, or limited scalability to small dimensions.

In addition, attempts have been made to decrease the floating body effect by decreasing the width of the channel body. For instance, a channel body having a decreased thickness may allow for an interface for the recombination of the minority carriers. However, such attempts have also resulted in source/drain regions having a smaller thickness, and therefore smaller contact area, resulting in source/drain regions having a thickness or width below a critical value. Attempts to widen source/drain regions have proven difficult, as they require complex epitaxial growth and lithography steps that yield inconsistent and ineffective results.

The present technology overcomes these and other problems by providing vertical channel array transistors (VCATs) having a reduced channel body width without requiring growth or addition to source/drain regions of the channel. Namely, the present technology has surprisingly found that by utilizing one or more protective dielectric materials, source/drain regions (or planned source/drain regions) may be protected, allowing a channel body thickness to be reduced without reducing a thickness or width of all or a portion of source/drain region. Thus, VCATs according to the present technology may have source/drain regions formed at or above the necessary critical dimension for contact width while also exhibiting a channel body having a width less than a source/drain region. Moreover, the present technology provides methods and systems for providing such VCATs that do not require complex processing steps, such as lithography and/or epitaxial growth of doped materials. Furthermore, the present technology has also found that a support mesh may be utilized to further protect semiconductors during processing, which may be further beneficial to high aspect ratio features and devices containing such features.

Although the remaining disclosure will routinely identify specific deposition and etch processes utilized for forming vertical cell array transistors (VCATs), such as a 4F² DRAM device, it will be readily understood that the systems and methods are equally applicable to other DRAM devices, including gate-all-around and Schottky barrier VCATs, other devices suffering from a floating body effect, and orientations thereof, as well as processes for forming such devices. Accordingly, the technology should not be considered to be so limited as for use with these specific devices or systems alone. The disclosure will discuss one possible semiconductor device that may include one or more components, utilizing one or more channels according to embodiments of the present technology before additional variations and adjustments to this apparatus according to embodiments of the present technology are described.

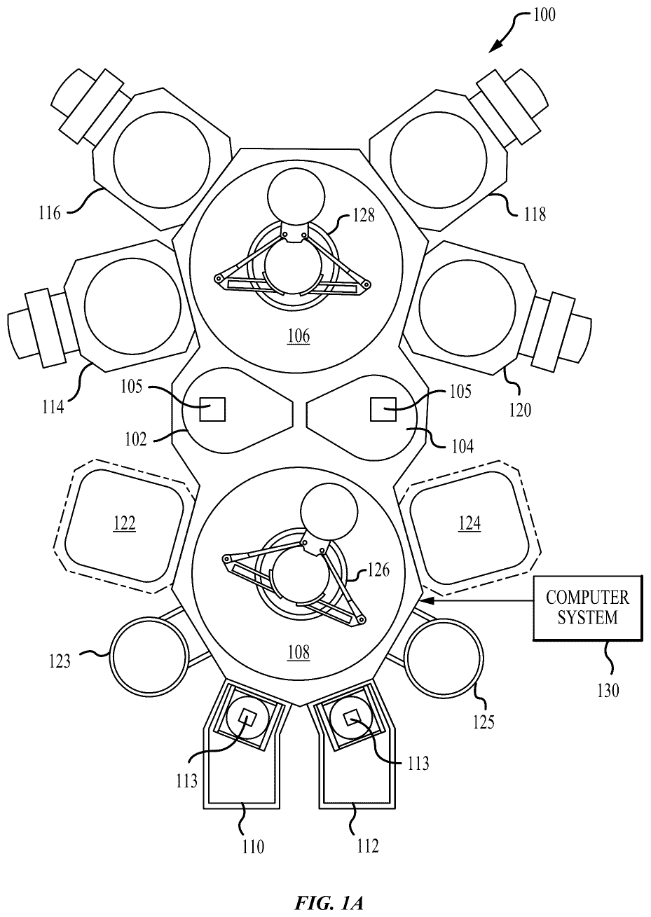

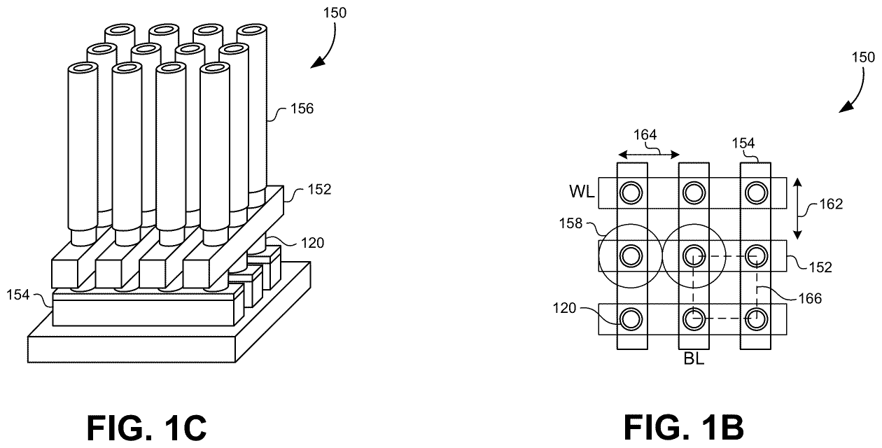

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular generally orthogonal grid pattern (where “generally orthogonal” may be within about 10° from orthogonal, such as less than or about 7.5°, such as less than or about 5°, such as less than or about 2.5°, such as less than or about 1° from orthogonal, or any ranges or values therebetween, where “generally” may be utilized to similarly vary “vertical”, “horizontal” and the like), it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166 for this conventional 4F² memory array for comparison to the simple memory array described below. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166.

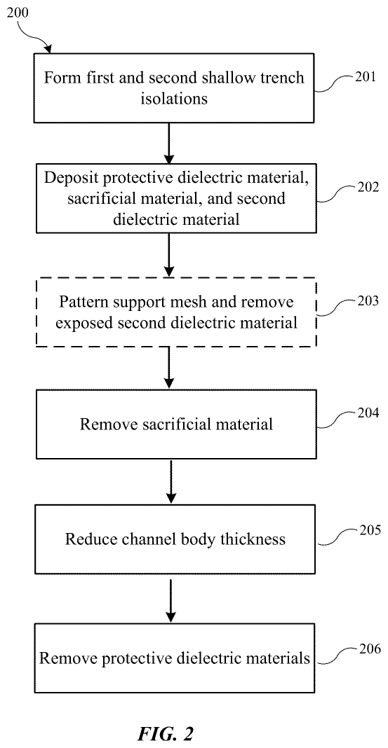

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. In addition, while the method may describe the formation method vertically, it should be understood that the other orientation from bit line to word line side may be utilized.

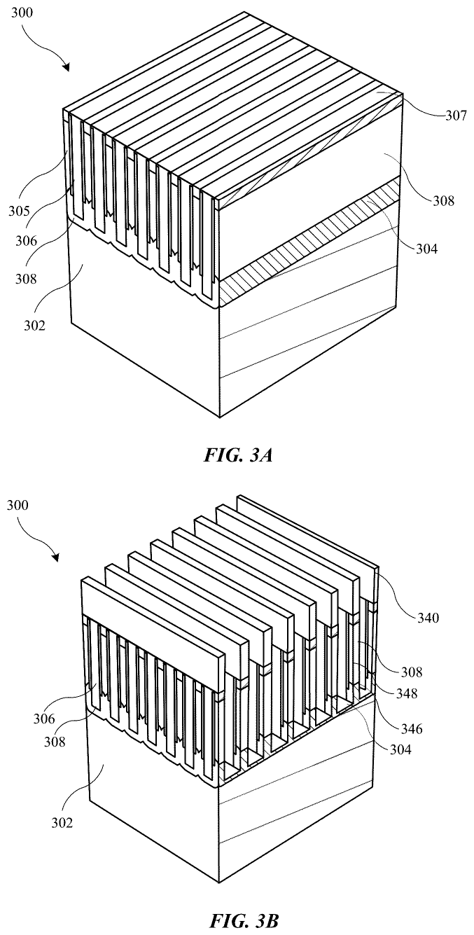

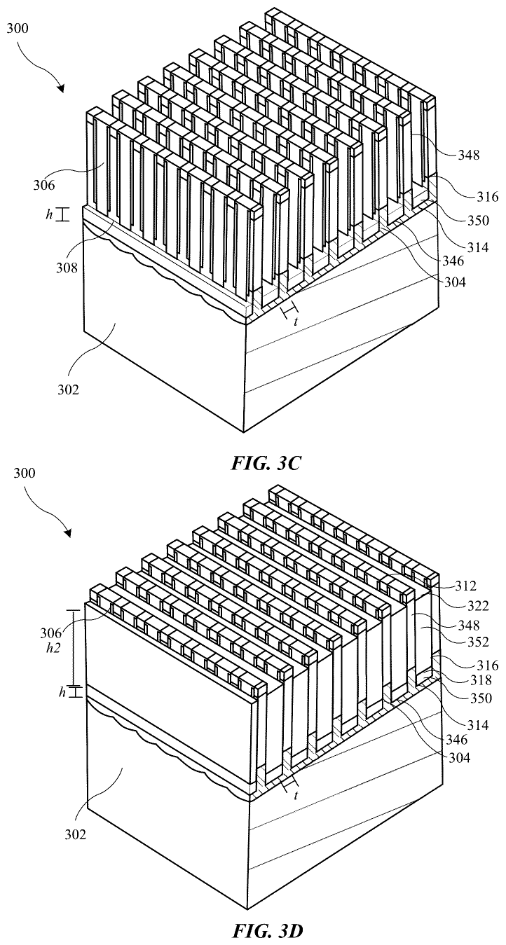

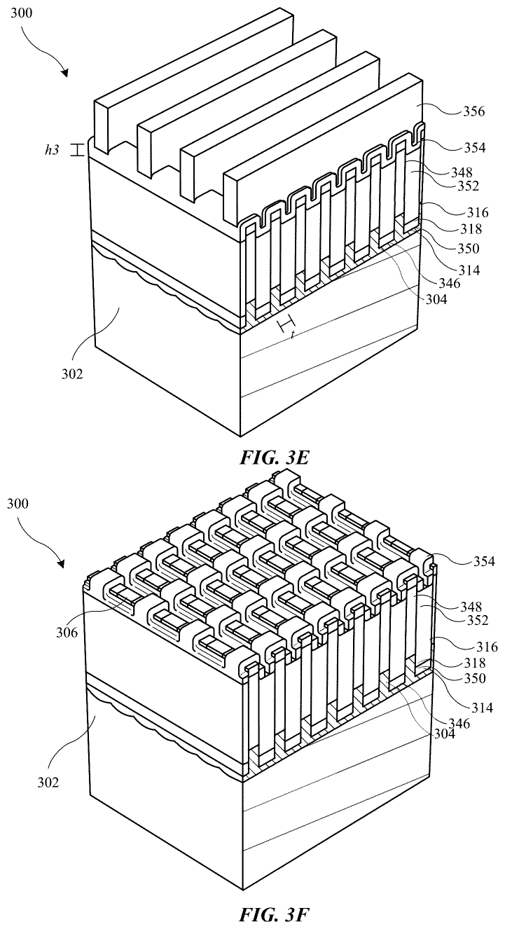

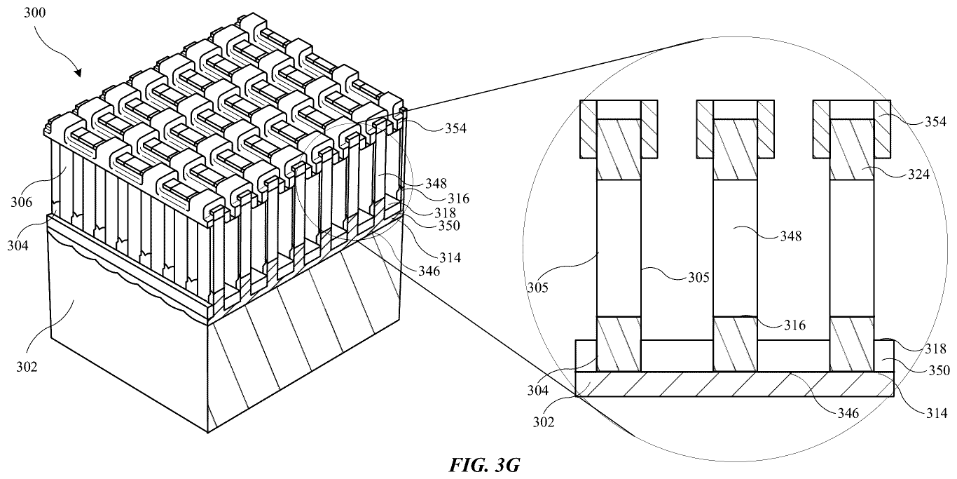

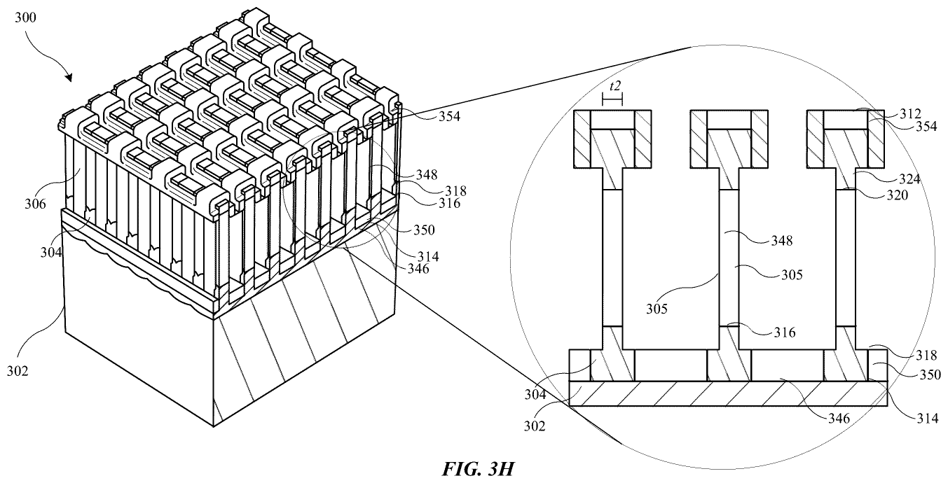

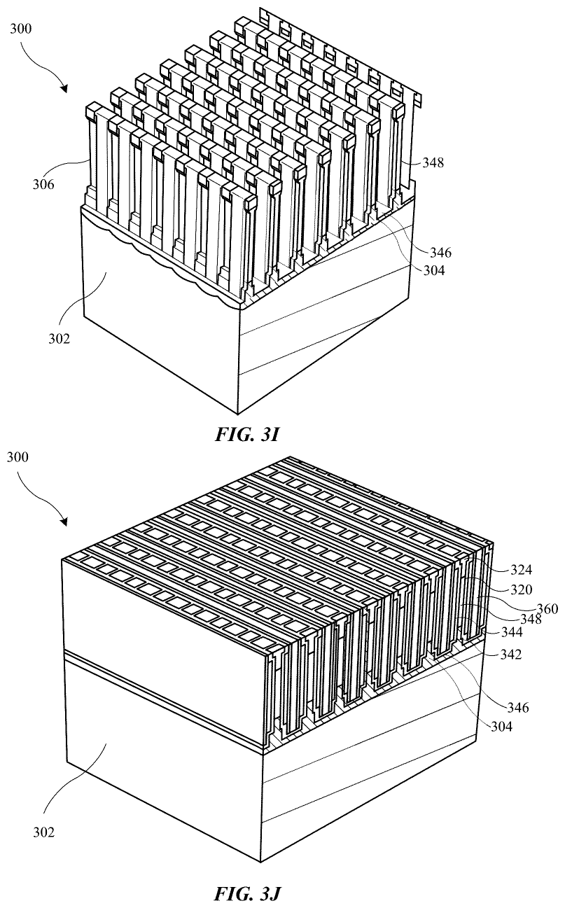

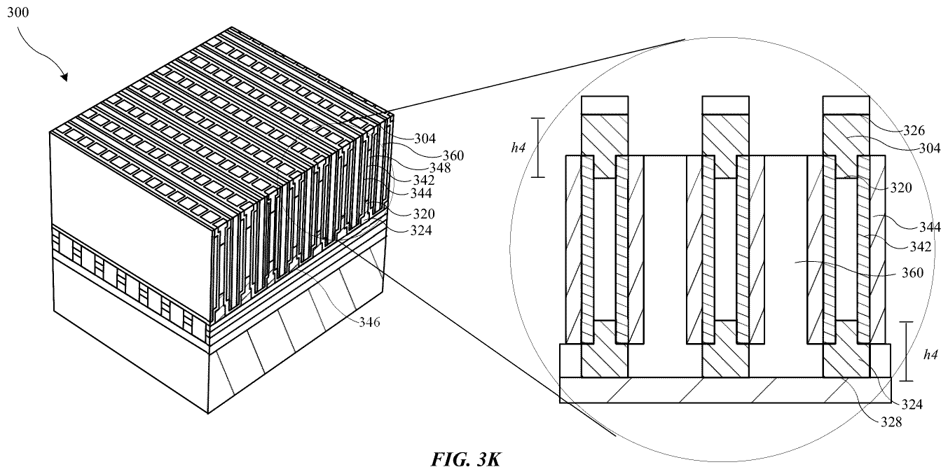

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in FIGS. 3A-3K, the illustrations of which will be described in conjunction with the operations of method 200. It is to be understood that FIG. 3A-3K illustrate only partial schematic views, and a semiconductor substrate may include further components as illustrated in the figures, as well as alternative components, of any size or configuration that may still benefit from aspects of the present technology.

Method 200 may or may not involve optional operations to develop the semiconductor structure to a particular fabrication operation. It is to be understood that method 200 may be performed on any number of semiconductor structures 300 or substrates 302, as illustrated in FIG. 3A-3K, including exemplary structures on which a selective deposition material may be formed. As illustrated in FIG. 3A substrate 302 may be any number of materials, such as a base wafer or substrate made of silicon or silicon-containing materials, germanium, other substrate materials, as well as one or more materials that may be formed overlying the substrate during semiconductor processing.

In embodiments, the structure 300 may be a semiconductor substrate, including bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 302 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers.

As illustrated in FIG. 3A, structure 300 is provided that includes a substrate 302 that has already undergone source/drain 304 formation, shallow trench isolation formation 308, and first dielectric material 306 fill in shallow trench isolations 308. However, it should be understood that, in embodiments, first source/drain regions 304 may instead be formed after front side processing is complete. In addition, two or more side walls 305 are formed between respective first shallow trench isolations 308, where the illustrated side walls 305 are spaced apart in a horizontally extending row generally perpendicular to a word line direction in this embodiment. However, as would be understood by one having skill in the art, in embodiments, shallow trench isolations may be first cut in a direction generally parallel to the word line direction. In embodiments, the dielectric material 306 may be any one or more dielectric materials discussed herein, such as silicon oxide or silicon nitride, or may be a low k dielectric, or combinations thereof.

In embodiments, when source/drain 304 formation is conducted as part of the front side processing, the formation may include one or more ion implants followed by a subsequent anneal process. The implant process may be a single implant or may include a series of multiple implants. When multiple implants are utilized, each implant may utilize the same ion, or different ions. Although, it should be understood that the source/drain region 304 may be formed from any suitable process. The method may include providing a semiconductor structure having first source/drain regions 304 for a plurality of vertical channels, and forming a plurality of word lines that contact the first source/drain regions. Overall, this process may incrementally form each stage of the transistor on top of a previous completed stage.

In embodiments, source/drain region 304 and channel body 348 (prior to thinning), may have a thickness t of greater than 11 nm, such as greater than or about 12 nm, such as greater than or about 13 nm, such as greater than or about 14 m, such as greater than or about 15 nm, such as greater than or about 16 nm, such as greater than or about 17 nm, such as greater than or about 18 nm, such as greater than or about 18 nm, such as greater than or about 19 nm, such as greater than or about 20 nm, such as greater than or about 21 nm, such as greater than or about 22 nm, such as greater than or about 23 nm, such as greater than or about 24 nm, or such as about 40 nm or less, such as about 35 nm or less, such as about 30 nm or less, such as about 25 nm or less, or any ranges or values therebetween.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), thermally enhanced chemical vapor deposition (CVD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

Nonetheless, at operation 201, method 200 may include forming both first shallow trench isolations as illustrated in FIG. 3A and second shallow trench isolations 346. For instance, in embodiments, a substrate 302 may be loaded into load lock 110,112, and transferred to a process chamber (such as process chamber 114) via robots 126, 128, where the semiconductor structure 300 may undergo mask 340 formation and second shallow trench isolation 346 formation, which may also be referred to as word line trench formation herein as the second shallow trench isolations 346 may extend in a generally horizontal direction that is generally parallel to the word line direction, at operation 201. For instance, FIG. 3B illustrates forming mask 340, which may be any patterning mask as known in the art, and etching of side walls 305 into channels 348 by etching in a direction extending in a second horizontal direction that is generally perpendicular to the first horizontal direction, in embodiments, utilizing mask 340. Namely, as discussed above for the formation of shallow trench isolations 308 between side walls 305, a pattern or mask 340 defining second shallow trench isolations 346 may be used to form the isolations between channels 348, which run in a row parallel or in plane with word lines, in this embodiment, formed by an etch process. The resulting channels 348 may have a uniform or nonuniform width, and/or a width generally equal to side walls 305. The second shallow trench isolations 346 may serve to isolate neighboring channels 348. Thus, as illustrated in FIGS. 3A and 3B, a semiconductor structure 300 may be provided that includes first and second shallow trench isolations, where the first shallow trench isolation may contain a deposited or filled dielectric material as discussed above. It should be understood that the substrate may be transferred between each operation step, or only a portion of the operation steps, as some operation steps may be completed in the same processing chamber.

As illustrated in FIG. 3C, at operation 202, a first protective dielectric material 350 may be formed at a first end 314 adjacent to substrate 302 of one or more respective word line trenches 346 in rows extending in the second horizontal direction (e.g. such that gate dielectric material 350 is generally parallel with the word line direction). The first protective dielectric material 350 may be any one or more dielectric material(s), such as a silicon oxide, silicon nitride, silicon oxycarbide, silicon oxynitride, silicon oxycarbonitride, combinations thereof, or other dielectric material as known in the art, formed utilizing any fill methods discussed above and as known in the art. Although the following description will regularly discuss silicon oxide or silicon nitride as a dielectric material and/or a spacer material, it is to be understood that any number of dielectric materials may be used in embodiments of the present technology, and the present technology should not be limited to any particular dielectric material in which features may be formed. Nonetheless, as will be discussed in greater detail below, it should be understood that other materials may be utilized at operation 202.

Notwithstanding the method, the first protective dielectric material 350 may be deposited at a height that extends from a first end 314 of a respective shallow trench isolation 346 to a height h that is generally coplanar with a top surface 316 of a source/drain region 304 or less. Namely, in embodiments, the first protective dielectric material 350 may be deposited at a height h to protect some or all of first source/drain region 304 from one or more etching processes. Thus, in embodiments, the first protective dielectric material 350 may be deposited at a height that is at least about 20% of a distance between first end 314 of shallow trench isolations 346 and top surface 316 of first source/drain regions 304, such as greater than or about 30%, such as greater than or about 40%, such as greater than or about 50%, such as greater than or about 60%, such as greater than or about 70%, such as greater than or about 75%, such as greater than or about 80%, such as greater than or about 85%, such as greater than or about 90%, such as greater than or about 95%, such as greater than or about 99%, or such as less than or about 99.9%, such as less than or about 99%, such as less than or about 95%, such as less than or about 90%, such as less than or about 85%, such as less than or about 80%, such as less than or about 75%, or any ranges or values therebetween. In such a manner, a width of all or a portion of source/drain region 304 may be maintained during one or more etching processes.

Operation 202 may also include depositing a sacrificial dielectric material 352 over first protective dielectric material 350. The sacrificial dielectric material 352 is shown in FIG. 3D as being deposited directly over first protective dielectric material 350. However, in embodiments, one or more layers may exist between first protective dielectric material 350 and sacrificial dielectric material 352. The sacrificial dielectric material may be any oxide, patterning material, such as a carbon containing pattern material, or combinations thereof, as well as other sacrificial materials as known in the art. Namely, in embodiments, the sacrificial dielectric material 352 may be selected to be easily etched while retaining first protective dielectric material 350 and second protective dielectric material 354.

Nonetheless, sacrificial dielectric material 352 may be deposited at a height h2 that extends from a top surface 318 (e.g. an internal surface) of the first protective dielectric material to a height between a top surface 312 of shallow trench isolation 346 and a plane generally coplanar with a bottom surface 320 of second source/drain regions 324 (shown in FIGS. 3J and 3K), or planned source drain regions. In such a manner, all or a portion of second source/drain regions 324 (or planned second source/drain regions) may be protected during a channel body 348 thinning operation or other etching processes. Thus, in embodiments, the sacrificial dielectric material 352 may be deposited at a height that extends at least about 10% of a distance between bottom surface 320 of second source/drain regions 324 to second end 312 (e.g. top surface) of shallow trench isolations 346, such as greater than or about 15%, such as greater than or about 20%, such as greater than or about 25%, such as greater than or about 30%, such as greater than or about 35%, such as greater than or about 40%, such as greater than or about 45%, such as greater than or about 50%, or such as less than or about 75%, or such as less than or about 70%, such as less than or about 65%, such as less than or about 60%, such as less than or about 55%, such as less than or about 50%, such as less than or about 45%, such as less than or about 40%, or any ranges or values therebetween. However, in embodiments, the sacrificial dielectric material 352 may be deposited to a height generally coplanar with bottom surface 320 of second/source drain regions 324. In such a manner, a width of all or a portion of source/drain region 324 may be maintained during one or more etching processes.

Operation 202 may also include depositing a second protective dielectric material 354 over sacrificial dielectric material 354. The second protective dielectric material 354 is shown in FIG. 3E as being deposited directly over sacrificial dielectric material 352. However, in embodiments, one or more layers may exist between second protective dielectric material 354 and sacrificial dielectric material 352. The second protective dielectric material 354 may be any one or more dielectric material(s), such as a silicon oxide, silicon nitride, silicon oxycarbide, silicon oxynitride, silicon oxycarbonitride, combinations thereof, or other dielectric material as known in the art, formed utilizing any fill methods discussed above and as known in the art. Nonetheless, as will be discussed in greater detail below, it should be understood that other materials may be utilized at operation 202. Moreover, in embodiments, first protective dielectric material 350 and second protective dielectric material 354 may be the same or different materials independent selected from one or more dielectric materials discussed above. Nonetheless, in embodiments, first protective dielectric material 350 and second protective dielectric material 354 may be selected to be retained during etching of the sacrificial dielectric material 352. Thus, in embodiments, first protective dielectric material 350 and/or second protective dielectric material 354 may be a material that is selective to the sacrificial material 352.

Notwithstanding the material selected, second protective dielectric material 354 is generally deposited on an upper surface of the sacrificial material. Moreover, the second protective dielectric material may generally be deposited to exhibit a height that protects all or a portion of second source/drain regions 324. Thus, in embodiments, the second protective dielectric material 354 may extend from a top surface 322 of the sacrificial dielectric material, to top surface 312 of shallow trench isolation 346. In embodiments, the a height h3 of the second protective dielectric material 354 may extend from a height that is between top surface 312 and a top surface 316 of a source/drain region 304 to top surface 312. Namely, in embodiments, the second protective dielectric material 354 may be deposited at a height h3 to protect some or all of second source/drain region 324 from one or more etching processes. Thus, in embodiments, the second protective dielectric material 354 may be deposited at a height that is at least about 40% of a distance from bottom surface 320 of second source/drain regions 324 to top surface 312 of shallow trench isolations 346, such as greater than or about 50%, such as greater than or about 60%, such as greater than or about 70%, such as greater than or about 75%, such as greater than or about 80%, such as greater than or about 85%, such as greater than or about 90%, such as greater than or about 95%, such as greater than or about 99%, or such as less than or about 99.9%, such as less than or about 99%, such as less than or about 95%, such as less than or about 90%, such as less than or about 85%, such as less than or about 80%, such as less than or about 75%, or any ranges or values therebetween. In such a manner, a width of all or a portion of source/drain region 304 may be maintained during one or more etching processes. However, in embodiments, second protective dielectric material 354 may be deposed over adjacent channels, and therefore extend above top surface 312 prior to recessing.

State differently, the first protective dielectric material 350 and second protective dielectric material 354 may extend from a contact surface 326, 328 of the respective source/drain regions (shown more clearly in FIG. 3K) towards an interior surface of the respective source/drain region 304, 324, a distance that is at least about 30% of a height of the respective source/drain region h4, such as greater than or about 35%, such as greater than or about 40%, such as greater than or about 45%, such as greater than or about 50%, such as greater than or about 55%, such as greater than or about 60%, such as greater than or about 65%, such as greater than or about 70%, such as greater than or about 75%, or such as less than or about 100%, such as less than or about 95%, such as less than or about 90%, such as less than or about 85%, such as less than or about 80%, or any ranges or values therebetween.

Regardless of the materials selected, at optional operation 203, a support mesh 330 may be formed from second protective dielectric material 354, which may provide additional structural stability to the semiconductor structure for further etching processes. As illustrated in FIG. 3E, a patterning mask 356, which may be the same or different from mask 340 may be applied over second protective dielectric material 354. As illustrated, the mask may be deposited extending across the semiconductor structure generally perpendicular to the word line direction, in order to provide additional support to shallow trench isolations 346 spaced apart in the word line direction. While four mask 356 patterns are illustrated, it should be clear that more or less may be utilized as necessary to provide support while allowing access to sacrificial dielectric material 354.

Nonetheless, after patterning mask 356 is formed, the exposed portion of second protective dielectric material 354 may be removed as illustrated in FIG. 3F. In embodiments, the exposed portion of second protective dielectric material 354 may be removed via etching, bottom punching, other methods as known in the art, or combinations thereof. The method used, as illustrated, may allow the second protective dielectric layer 354 to retain connected rows extending in a bit line direction (e.g. generally perpendicular to the word line direction) and surrounding second source/drain regions 324, while exposing sacrificial dielectric material 352 between adjacent rows. However, it should be clear that, in embodiments, second protective dielectric material 354 may be deposited within shallow trench isolations 346, and not require recessing.

After operation 202 or optional operation 203, the sacrificial dielectric material 352 may be removed while retaining first protective dielectric material 350 and second protective dielectric material 354, at operation 204, and as illustrated in FIG. 3G. Namely, as first protective dielectric material 350 and second protective dielectric material 354 are materials selective to the sacrificial dielectric material 352, the sacrificial dielectric material 352 may be easily removed utilizing methods known in the art without damaging the channel body 348, first source/drain region 304, and/or second source/drain region 324. For instance, in embodiments, removal may include a selective wet etch, a vapor etch, a plasma etch, or the like, in order to remove sacrificial film 352.

As illustrated in FIG. 3H, after removal of sacrificial dielectric material 352, one or more of the channel bodies 348 may be thinned or reduced in thickness, at operation 205 by etching the exposed side walls 305 of the channel bodies 348. Namely, the first source/drain regions 304 and second source/drain regions 324 may maintain their initial thickness t, which one or more channel bodies 348 are thinned to a second thickness t2. In embodiments, the second thickness t2 may be greater than or about 5% less than a thickness t, such as greater than or about 7.5% less, such as greater than or about 10% less, such as greater than or about 12.5%, such as greater than or about 15% less, such as greater than or about 20% less, such as greater than or about 25% less, such as greater than or about 30% less, such as greater than or about 35% less, such as greater than or about 40% less, such as greater than or about 45% less, such as greater than or about 50% less, such as greater than or about 55% less, such as greater than or about 60% less, such as greater than or about 65% less, or any ranges or values therebetween. In embodiments, a portion of one or more source/drain regions 304, 324 may also be thinned according to the above amounts. In such embodiments, less than or about 40% of the height h4 of the respective source/drain regions may be thinned, such as less than or about 35%, such as less than or about 30%, such as less than or about 25%, such as less than or about 20%, such as less than or about 15%, such as less than or about 10%, such as less than or about 5%, or any ranges or values therebetween.

Stated differently, in embodiments, the second thickness t2 may be less than 11 nm, such as less than or about 10.5 nm, such as less than or about 10 nm, such as less than or about 9.5 nm, such as less than or about 9 nm, such as less than or about 8.5 nm, such as less than or about 8 nm, such as less than or about 7.5 nm, or any ranges or values therebetween.

In embodiments, the reduction in thickness may be conducted utilizing a selective silicon etch. Additionally or alternatively, the silicon of the channel bodies 348 may be oxidized and wet etched depending upon the materials selected for first protective dielectric material 350 and second protective dielectric material 354. Nonetheless, it should be clear that other methods, or one or more methods in combination, for thinning the channel bodies 348 may be selected based upon the selectivity to the channel bodies 348 without being selective to first protective dielectric material 350 and second protective dielectric material 354.

After the channel body 348 has been reduced in thickness at operation 205, the first protective dielectric material 350 and second protective dielectric material 354 may be removed at operation 206, as illustrated in FIG. 3I. Thus, the semiconductor structure 300 may re-enter a normal process flow for VCAT devices, such as a 4F² DRAM array.

For instance, referring to FIG. 3J, a gate dielectric 342 may be deposited generally along an exterior perimeter of shallow trench isolation 346. The gate dielectric 342 may be any one or more of the dielectric materials discussed above, and may be an oxide, in embodiments. Moreover, a gate material 344 may be deposited over the gate dielectric 342, generally along an exterior perimeter of the gate dielectric 342 lined shallow trench isolation 346. The gate material may be a material such as a low-resistance metal, including tungsten, titanium nitride, titanium, ruthenium, cobalt, molybdenum, the like, or combinations thereof. Nonetheless, as illustrated, after deposition of the gate dielectric 342 and gate metal 344, the bottom of gate dielectric 342 and gate metal 344, adjacent to substrate 302, may be removed, such as by polishing or bottom punching, to isolate adjacent word lines. Furthermore, in embodiments, a fill dielectric 360 may be introduced between adjacent gate metals 344. Nonetheless, second source/drain regions 324 may be formed adjacent to top surface 312, such as by ion implant or any other methods discussed above in regards to first source/drain regions 304.

However, in embodiments, it should be understood that one or both of first source/drain regions 304 and second source/drain regions 324 may instead be formed as Schottky contacts. Namely, in embodiments, such a contact as a source/drain region(s) may further reduce minority carrier injection and the floating body effect, and therefore further decreases in leakage current. For instance, a metal silicide may be formed as one or more source/drain regions. In such an embodiment, the first or second source/drain region 304, 324 may undergo a metallization process, such as silicidation to form a metallized interface. For instance, a metal layer may be applied over first or second source/drain regions 304, 324 which is subsequently exposed to a silicidation process. In embodiments, the metal layer may be tungsten, molybdenum, titanium, zirconium, nickel, hafnium, cobalt, tin, tantalum, platinum, iron, niobium, palladium, a metal-containing species thereof, alloys thereof, or combinations thereof. Thus, the resulting interface may be a metallized layer of any one or more of the above metals and the channel material, such as silicon. In such an example only, the interface layer may be a titanium silicide, molybdenum silicide, hafnium silicide, or a combination thereof. The contact may also contain one or more ion implants, such as of boron, phosphorus, arsenic, or some other material in order to produce a barrier height of greater than or about 0.60 V, and which may produce a barrier height of greater than or about 0.65 V, greater than or about 0.70 V, greater than or about 0.75 V, greater than or about 0.80 V, greater than or about 0.85 V, or more.

Notwithstanding the doping methods utilized, the final structure may be illustrated in FIG. 3K. Surprisingly, as illustrated, the thinning of channel body 348 of the present technology also allows for a relatively thicker word line metal 344 to be utilized without increasing the pitch of the semiconductor structure. Namely, as shown in FIG. 3K, due to the thinner body 348 as compared to source drain contacts 324, 326, a thicker word line material may be formed without contacting an adjacent word line or risking a short due to lack of isolation. Thus, the semiconductor structure of the present technology may also provide a reduced resistivity in addition to reduced floating body effect.

Regardless of how or when the source/drain regions 304 and 324 are formed, the semiconductor structure 300 may re-enter a normal process flow for a vertical cell DRAM array, such as a 4F² DRAM array, and undergo one or more further processing steps. For instance, the semiconductor structure may undergo contact redistribution, bonding pad formation, and/or copper contact formation. Nonetheless, semiconductor structure may exhibit a reduced gate floating body effect and/or word line resistivity.

It should be appreciated that the specific steps illustrated in the figures provide particular methods of forming 4F² DRAM arrays according to various embodiments. Other sequences of steps may also be performed according to alternative embodiments. For example, alternative embodiments may perform the steps outlined above in a different order. Moreover, the individual steps illustrated in the figures may include multiple sub-steps that may be performed in various sequences as appropriate to the individual step. Furthermore, additional steps may be added or removed depending on the particular applications. Many variations, modifications, and alternatives also fall within the scope of this disclosure.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A vertical cell array transistor (VCAT), comprising:
one or more bit lines arranged in a first horizontal direction;
one or more word lines arranged in a second horizontal direction;
one or more channels extending in a vertical direction that is generally orthogonal to the first horizontal direction and the second horizontal direction such that the one or more word lines intersect with a gate region of the one or more channels;
wherein the one or more channels have at least one source/drain region at a first end, a second end, or both a first end and a second end of the one or more channels and a channel body disposed between the first end and the second end, wherein the channel body has a thickness that is greater than or about 5% less than a thickness of at least a portion of the at least one source/drain region.

2. The vertical cell array transistor (VCAT) of claim 1, wherein the one or more channels comprise a first source/drain region at a first end and a second source/drain region at the second end, wherein the channel body has a thickness that is greater than or about 5% less than a thickness of at least a portion of the first source/drain region and the second source/drain region.

3. The vertical cell array transistor (VCAT) of claim 1, wherein at least a portion of the at least one source/drain region has a greater thickness than a second portion of the at least one source/drain region.

4. The vertical cell array transistor (VCAT) of claim 1, wherein greater than or about 20% of the at least one source/drain region has a thickness greater than the thickness of the channel body.

5. The vertical cell array transistor (VCAT) of claim 4, wherein the at least one source/drain region has a contact end and an internal end, wherein the contact end has the thickness greater than the thickness of the channel body.

6. The vertical cell array transistor (VCAT) of claim 5, wherein the internal end has a thickness generally equal to a thickness of the channel body.

7. The vertical cell array transistor (VCAT) of claim 2, wherein the channel body has a thickness that is greater than or about 10% less than a thickness of at least a portion of the first source/drain region and the second source/drain region.

8. The vertical cell array transistor (VCAT) of claim 1, wherein the channel body has a thickness of less than 11 nm.

9. The vertical cell array transistor (VCAT) of claim 8, wherein the channel body has a thickness of less than or about 10 nm.

10. A vertical cell array transistor (VCAT), comprising:
a plurality of bit lines arranged in a first horizontal direction;
a plurality of word lines arranged in a second horizontal direction;
a plurality of channels extending in a vertical direction that is generally orthogonal to the first horizontal direction and the second horizontal direction such that the plurality of word lines intersect with a gate region of the plurality of channels;
wherein the plurality of channels each have a first source/drain region at a first end, a second source/drain region at a second end, and a channel body disposed between the first end and the second end, wherein the channel body has a thickness that is greater than or about 5% less than a thickness of at least a portion of the first source/drain region and the second source/drain region.

11. A method of forming a vertical cell array transistor (VCAT), comprising:
etching a substrate to form one or more shallow trench isolations and a plurality of vertically extending channels;
depositing a first protective dielectric material in the shallow trench isolation adjacent to a first source/drain region at a first end of the vertically extending channel;
depositing a sacrificial dielectric material over the first protective dielectric material;
depositing a second protective dielectric material over the sacrificial dielectric material adjacent to a second source/drain region at a second end of the vertically extending channel;
removing the sacrificial dielectric material; and
reducing a thickness of a channel body of the one or more of the vertically extending channels, wherein the channel body is disposed between the first source/drain region and the second source/drain region.

12. The method of claim 11, further comprising etching the second protective dielectric material to form a support mesh.

13. The method of claim 11, further comprising reducing a thickness of a portion of the first source/drain region, the second source/drain region, or a combination thereof.

14. The method of claim 11, wherein the first protective dielectric material is deposited extending from the first end to a height that is generally coplanar with a top surface of the first source/drain region or less.

15. The method of claim 14, wherein the sacrificial dielectric material is deposited extending from a top surface of the first protective dielectric material to a height that is greater than or generally coplanar with a bottom surface of the second source/drain region.

16. The method of claim 15, wherein the second protective dielectric material is deposited extending from a height that is greater than or generally coplanar with the bottom surface of the second source/drain region to the second end of the vertically extending channel.

17. The method of claim 11, further comprising removing the first protective dielectric material and the second protective dielectric material, and depositing a gate dielectric layer and a gate metal around a perimeter of the one or more shallow trench isolations.

18. The method of claim 17, wherein greater the channel body is reduced in thickness by greater than or about 5%.

19. The method of claim 11, wherein reducing the thickness of the channel body comprises a selective silicon etch, an oxidation and wet etch, or a combination thereof.

20. The method of claim 12, wherein the sacrificial dielectric material comprises a material that can be selectively etched without etching the first protective dielectric material and the second protective dielectric material.
